(19) United States
(12) Patent Application Publication
(10) Pub. No.: US 2002/0079113 A1
(43) Pub. Date: Jun. 27, 2002

(54) Electrically and environmentally sealed mechanical control device for an electronic device

(76) Inventors: David Wallis, Atlanta, GA (US); Jeffrey P. Hughes, Lawrenceville, GA (US); Khalid Kidari, Loganville, GA (US); Alan J. Schlenz, Snellville, GA (US)

Correspondence Address: SCIENTIFIC-ATLANTA, INC., INTELLECTUAL PROPERTY DEPARTMENT, 5030 SUGARLOAF PARKWAY, LAWRENCEVILLE, GA, 30044, US

(21) Appl. No.: 09/747,536

(22) Filed: Dec. 21, 2000

(51) Int. Cl. H05K 9/00

(52) U.S. Cl. 174/35 R

(57) ABSTRACT

A device including a housing (305) for enclosing electronic components and having an aperture therethrough. The device further includes a control element (300) and is inserted through the aperture. The control element (300) has a control end and a mating end, wherein when the control element (300) is inserted into the aperture of the housing (305), the mating end mates with an electronic component and is controlled by the control end. A sealing element (315) is placed around a groove (515) of the control element (300) for sealing the control element (300), after insertion into the housing (305), from the surrounding environment elements; and then a retaining means (325) is placed around the control element (300) on a region of the control element (300) that extends into an interior of the housing (305), wherein the retaining means (325) exerts force onto the housing (305), thereby securing the control element (300) within the housing (305).

### RELATED APPLICATIONS

This patent application is related to U.S. patent application Docket No. A-7057, entitled Self Aligning, Weather Resistant Electrical Switch by William G. Mahoney, and filed on even date with this patent application.

### FIELD OF THE INVENTION

This invention relates generally to broadband communications systems, such as cable television systems, and more specifically to tap products used in such systems.

### BACKGROUND OF THE INVENTION

A communication system 100, such as a two-way cable television system, is depicted in FIG. 1. The communication system 100 includes headend equipment, 105 for generating forward signals that are transmitted in the forward, or downstream, direction along a communication medium, such as a fiber optic cable 110, to an optical node 115 that converts optical signals to radio frequency (RF) signals. The RF signals are further transmitted along another communication medium, such as coaxial cable 120, and are amplified, as necessary, by one or more distribution amplifiers 125 positioned along the communication medium. Taps 130 included in the cable television system split off portions of the forward signals for provision to subscriber equipment 135, such as set top terminals, computers, and televisions. In a two-way system, the subscriber equipment 135 can also generate reverse signals that are transmitted upstream, amplified by any distribution amplifiers 125, converted to optical signals, and provided to the headend equipment 105.

A cable television tap 130 that splits the forward signal is depicted in FIG. 2. The tap 130 includes an input port 205 for receiving the signal, an output port 210 for passing the signal through to other portions of the communication system 100, and subscriber ports 215, each of which couples a portion of the signal to subscriber equipment. A tap 130 commonly includes four, eight, or sixteen subscriber ports 215, although an even larger number of subscriber ports 215 can be included if necessary.

AC (alternating current) power can also be provided through the cable television system 100 for powering telephones and other subscriber equipment. In this case, the AC power typically travels through the same distribution system, including the taps 130, so that it can be provided to the subscriber equipment on the same communication medium that provides the information signal. In operation, the tap 130, which includes a power distribution unit (PDU) 220, receives the forward signal, including the AC power, and provides, via AC port device connectors 225, a plurality of AC power outputs and, via the subscriber ports 215, a plurality of information signal outputs.

While conventional electronic devices, such as the multimedia tap 130 and the PDU 220, meet the objective of providing information signals while also supplying AC power to the subscriber, there are some disadvantages presented by the conventional electronic devices. One disadvantage is in order to activate any internal components, the faceplate 215 and the cover 230 need to be removed via a number of screws or fasteners thereby allowing the surrounding weather to potentially adversely affect the internal electronics. Additionally, after opening and closing a conventional electronic device, the integrity of the seal may be compromised. Therefore, in light of the disadvantages to the cable operator, what is needed is a less cumbersome mechanism that offers flexibility in activating or deactivating internal components. In addition, the product enhancements need to incorporate the required specifications regarding the environmental and electrical sealing while enhancing the product with user-friendly features.

### BRIEF DESCRIPTION OF THE DRAWINGS

FIG. 1 depicts a communications system, such as a cable television system.

FIG. 2 is an illustration of a conventional multimedia tap including a power distribution unit that is used in such systems as shown in FIG. 1.

FIG. 3 shows a cut out view of a housing showing a control device in accordance with the present invention.

FIG. 4 is an example of a control device of FIG. 3 controlling an electronic component within an electronic device.

FIG. 5 shows a control shaft of the control device of FIG. 3.

FIG. 6 is a bottom view illustration of a retaining clip exerting force against a housing wall thereby sealing the control device in accordance with the present invention.

FIG. 7 shows a side view of the retaining clip of FIG. 6.

### DETAILED DESCRIPTION OF A PREFERRED EMBODIMENT

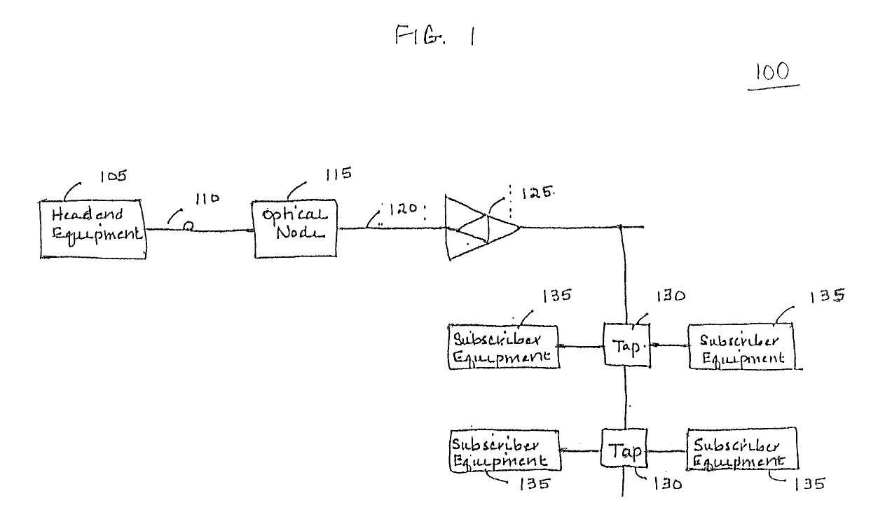

FIG. 1 shows a communications system 100, such as a cable television system, having both forward and reverse paths, i.e., having the ability to communicate downstream in the forward direction and upstream in the reverse direction. The cable television system 100 includes a headend 105 for receiving satellite signals that are demodulated to baseband or an intermediate frequency (IF). The baseband signal is then converted to cable television signals that are routed throughout the system 100 to subscriber equipment 135, such as set top decoders, televisions, or computers, located in the residences or offices of system subscribers. The headend 105 can, for instance, convert the baseband signal to an optical signal that is transmitted over fiber optic cable 110, in which case a remotely located optical node 115 converts the optical signal to an electrical radio frequency (RF) signal for further transmission through the system 100 over coaxial cable 120. Taps 130 located along the cable 120 at various points in the distribution system split off portions of the RF signal for routing to subscriber equipment 135 coupled to subscriber drops provided at the taps 130.

The system 100, as mentioned, also has reverse transmission capability so that signals, such as data, video, or voice signals, generated by the subscriber equipment 130 can be provided back to the headend 105 for processing. The reverse signals travel through the taps 130 and any nodes 115 and other cable television equipment, e.g., reverse amplifiers, to the headend 105. In the configuration shown in FIG. 1, RF signals generated by the subscriber equipment 135 travel to the node 115, which converts the RF signals to optical signals for transmission over the fiber optic cable 110 to the headend 105.

As mentioned briefly in the Background of the Invention, electronic devices generally have internal components that need to be physically accessed to begin processing information. For example, the multimedia tap 130 requires the faceplate 215 and the PDU cover 230 to be completely removed to access internal jumpers. Occasionally, when a housing is opened or a faceplate or a cover is removed from an electronic device, the internal electronics may be adversely affected due to the weather. Also, the sealing for EMI shielding may become damaged, thereby degrading the signals that are transmitted to the subscriber and headend. Additionally, opening a housing and removing a cover consumes time that is minimized if electronic components within a module are controlled with external devices.

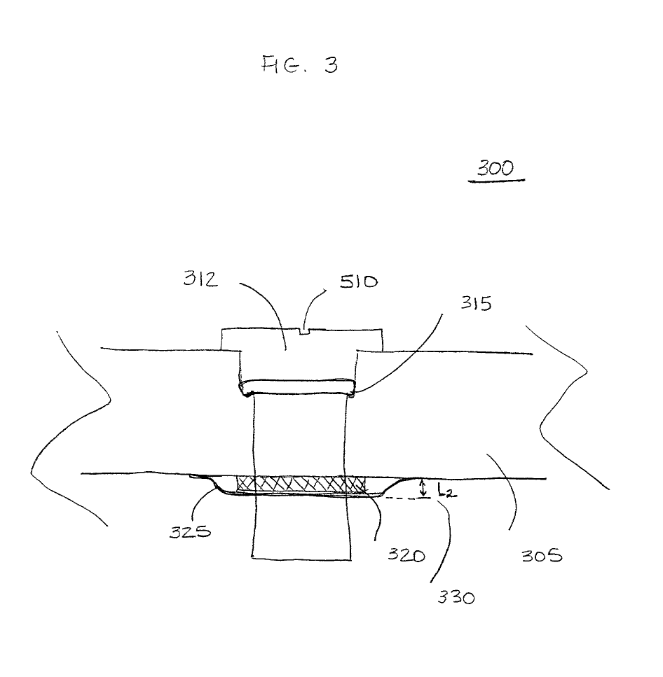

FIG. 3 shows a cut out view of a housing 305 including a mechanical control device 300 in accordance with the present invention. It will be appreciated that the mechanical control device 300 is designed to control an internal component as long as the internal component and the control device 300 mate And the internal component can be controlled by a switching means formed on an internal portion of the control device 300. Advantageously, without having to open the housing 305 or remove the cover, the internal component can be controlled while the control device 300 maintains a seal with the housing 305 to protect the internal components from weather and other environmental contaminates, and also provides isolation from electromagnetic interference (EMI). For example, a typical electronic device meets the sealing specification of 10 pounds per square inch (psi) and the EMI isolation specification of 120 decibels (dBs).

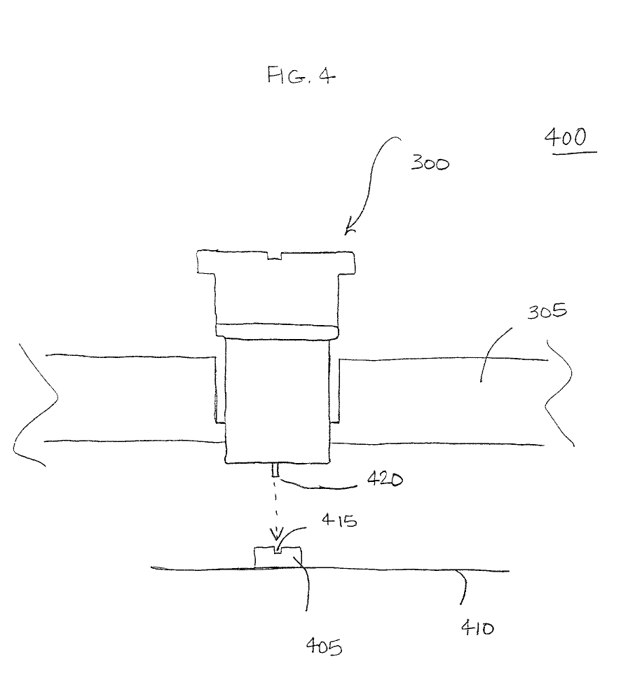

By way of example, FIG. 4 shows an example in which the control device 300 has been inserted into the housing 305 for controlling an internal component within an electronic module 400. In the example, a potentiometer 405 is soldered onto a printed circuit board 410 and then enclosed within the housing 305. A slot 415 is typically used to tune the potentiometer 405 to the desired value. Before the control device 300 is inserted into an aperture within the housing 305, the control device 300 is equipped with a flat blade 420 designed to mate with the slot 415 of the potentiometer 405. The potentiometer 405 can then be tuned via the control device 300 without opening the housing 305.

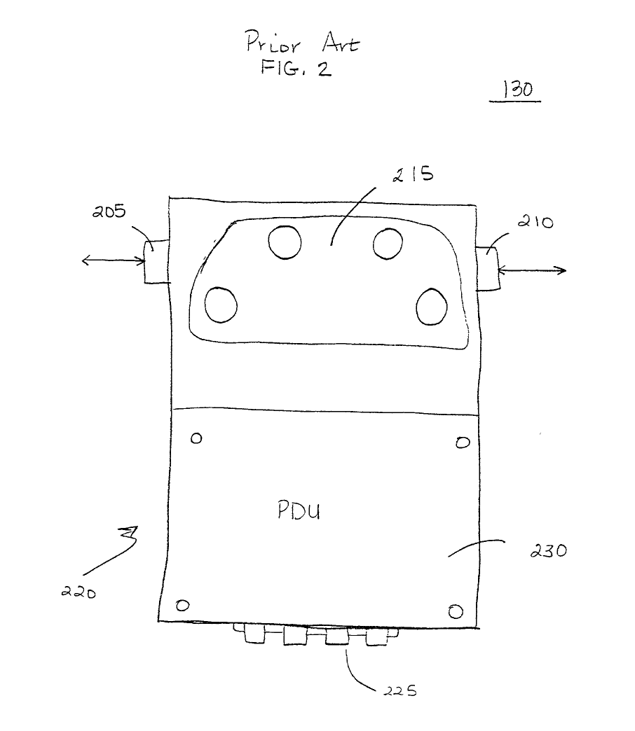

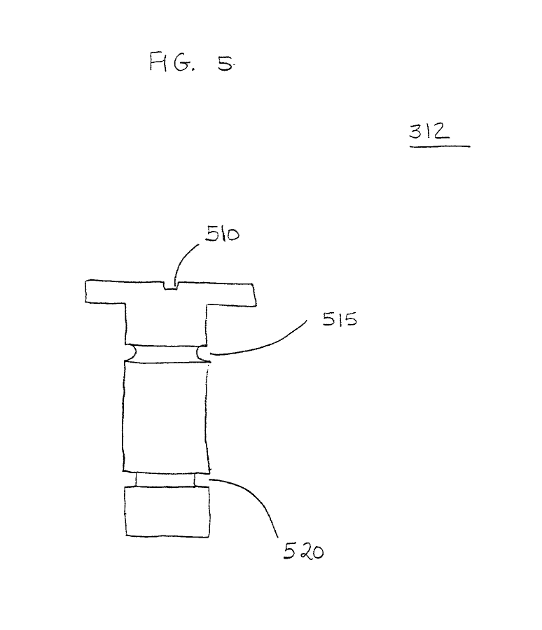

FIG. 5 shows a control shaft 312 of the control device 300. When properly situated within the housing 305 of FIG. 3, the control shaft 312 can be rotated via a groove 510 formed onto one end, a control end, of the control shaft 312. When the control device 300 is fully inserted, the control end is accessible from the outside of the housing 305 (FIG. 3). For environmental sealing, a sealing element 315, shown in FIG. 3, is placed around the control shaft 312 within a circular groove 515. During assembly of the device 300, the control shaft 312 is inserted through an aperture in the housing 305 or cover plate, such as the cover plate 230 on the PDU 220 (FIG. 2). The length and width of the control shaft 312 is such to accommodate the required reach to activate and deactivate the internal component as well as the consideration of the thickness of the housing 305.

Referring again to FIG. 3, after insertion of the control shaft 312 through the housing 305, a shielding element 320 is positioned around the control shaft 312 from the inside of the housing 305. The shielding element 320 shields the internal components from EMI or other variations of interference. The shielding element 320 is formed from an appropriate shielding material, such as a wire mesh or a polymer material.

Referring FIG. 3 in conjunction with FIG. 5, added retention and sealing of the control shaft 312 while fully seated within the housing 305 is achieved by using an internal retaining clip 325. The retaining clip 325 mates with a groove 520 encircling the shaft 312.

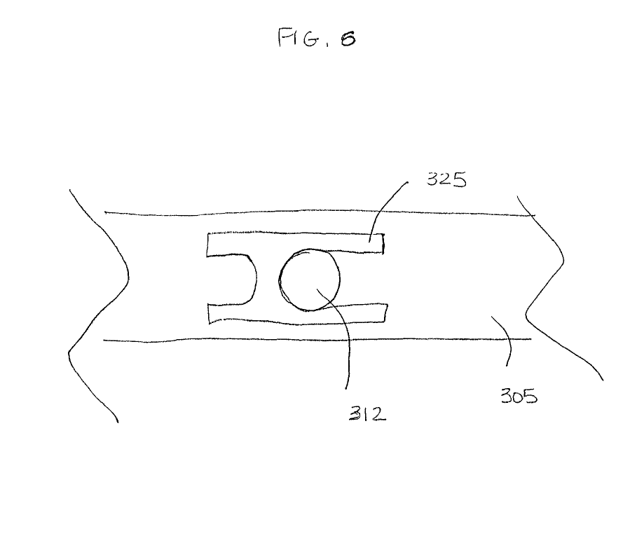

FIG. 6 shows an embodiment of a retaining clip 325 that is frictionally held in the groove 520 of the control shaft 312 so that the opposite ends of the clip 325 exerts pressure against the housing 305. The retaining clip 325 exerts pressure onto the control shaft 312 in an inward direction so that the control end of the control device 300 is pressed firmly to the exterior of the housing 305. The pressure tightly seals the control end of the control shaft 312 to the housing 305, thereby contributing to satisfaction of the sealing specification.

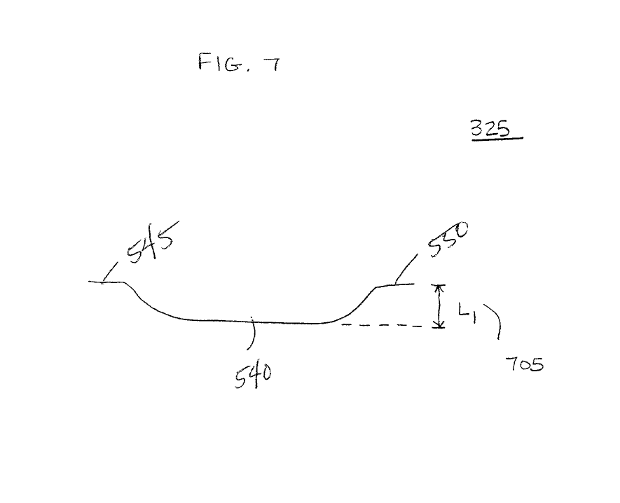

FIG. 7 shows the retaining clip 325 in a resting position. The retaining clip 325 includes a substantially planar central region 540 and opposing end portions 545, 550 that are substantially co-planar with one another. In the resting position, the plane in which the central region 540 of the retaining clip 325 is formed is separated from the plane in which a distance of L1 705 forms the opposing ends. Referring to FIG. 3, the retaining clip 325 is slightly deformed to exert pressure on the housing 305 at its opposing ends and to exert pressure in the opposite direction on the control device 300. As a result, the distance between the ends of the clip 325 and the central region of the clip 325 is shown as L₂ 330. The distance L₂ is likely to be slightly less than the distance L₁. As mentioned briefly hereinabove, in the forced position of FIG. 3, the retaining clip 325 tightly seals the control shaft 312 into the housing 305 to prevent ingress of the surrounding environment.

In summary, use of the control device in accordance with the preferred embodiment of the present invention allows internal components of an electronic module to be controlled from the outside without having to open a housing or remove a faceplate. Additionally, the environmental and electrical specifications are met through use of the weather resistant o-ring 315, retaining clip 325, and EMI shield 320. Thus, the present invention allows the operator savings in time and money due to its flexibility in use and operation.

What is claimed is:

1. A device, comprising:
a housing having an aperture formed therethrough, wherein the housing encloses electronic components;
a control element having a control end and a mating end, wherein the control element is inserted through the aperture of the housing such that the mating end mates with an electronic component, wherein rotation of the control end results in switchable control of the electronic component;
a sealing element placed around the control element for providing a seal between the control element and the housing; and
retaining means placed around the control element on a region of the control element that extends into an interior of the housing, wherein the retaining means exerts force onto the housing, thereby securing the control element within the housing.

2. The device of claim 1, further comprising:
a shielding element for shielding against ingress and egress of interference surrounding the electronic components.

3. The device of claim 1, further comprising:
actuating means on the control end for rotating the control element within the housing.

4. The device of claim 3, wherein the actuating means is a slot formed in the control end of the control element.

5. The device of claim 1, wherein the device is a multimedia tap.

6. A communications system for transmitting and receiving information signals, the communications system, comprising:
a headend for generating forward signals and for receiving reverse signals;
a plurality of electronic devices for processing the forward and reverse signals, an electronic device comprising:
a housing having an aperture formed therethrough for enclosing electronic components;
a control element having a control end and a mating end, wherein the control element is inserted through the aperture of the housing such that the mating end mates with an electronic component, wherein rotation of the control end results in switchable control of the electronic component;
a sealing element placed around the control element for providing a seal between the control element and the housing; and
retaining means placed around the control element on a region of the control element that extends into an interior of the housing, wherein the retaining means exerts force onto the housing, thereby securing the control element within the housing.

7. The communications system of claim 6, wherein the electronic device further comprises:
a shielding element for shielding against ingress and egress of interference surrounding the electronic components.

8. The communications system of claim 7, wherein the shielding element is a wire mesh shield.

9. The communications system of claim 6, further comprising:
actuating means on the control end of the control element within the housing.

10. The communications system of claim 9, wherein the actuating means is a slot formed in the control end of the control element.

11. The communications system of claim 6, wherein the electronic device is a power distribution.

12. A power distribution unit for passing power through a multimedia tap, the power distribution unit, comprising: a housing having an aperture formed therethrough, wherein the housing encloses electronic components;
a control element having a control end and a mating end, wherein the control element is inserted through the aperture of the housing such that the mating end mates with an electronic component, wherein rotation of the control end results in switchable control of the electronic component;
a sealing element placed around the control element for providing a seal between the control element and the housing; and
retaining means placed around the control element on a region of the control element that extends into an interior of the housing, wherein the retaining means exerts force onto the housing, thereby securing the control element within the housing.

13. The power distribution unit of claim 12, further comprising:
a shielding element for shielding against ingress and egress of interference surrounding the electronic components.

14. The power distribution unit of claim 12, further comprising:
actuating means on the control end of the control element for rotating the control element within the housing.

15. The power distribution unit of claim 14, wherein the actuating means is a slot formed in the control end of the control element.
